(19) United States
(12) Patent Application Publication
(10) Pub. No.: US 2025/0337146 A1
(43) Pub. Date: Oct. 30, 2025

(54) Power divider/combiner component of the coaxial guide type using SIW technology

(71) Applicant: THALES, Meudon (FR)

(72) Inventors: Stéphane DENIS, ETRELLES (FR); Audrey THORINIUS, ETRELLES (FR); Laurent BILLAND, ETRELLES (FR); Anne-Catherine TANGUY, ETRELLES (FR)

(21) Appl. No.: 19/193,177

(22) Filed: Apr. 29, 2025

(30) Foreign Application Priority Data
Apr. 29, 2024 (FR) 24 04450

(51) Int. Cl. H01P 5/12; H05K 1/02; H05K 1/11

(52) U.S. Cl. CPC H01P 5/12; H05K 1/0213; H05K 1/115

(57) ABSTRACT

A power divider/combiner component of the coaxial guide type, characterized in that it is fabricated using “substrate integrated waveguide” technology, in a multilayer integrated circuit board, which includes a stack of a plurality of conductive layers separated from each other by insulating layers.

### REFERENCE TO RELATED APPLICATION

This application is a U.S. non-provisional application claiming the benefit of French Patent Application No. 24 04450 filed on Apr. 29, 2024, the contents of which are incorporated herein by reference in their entirety.

### TECHNICAL FIELD OF THE INVENTION

The present invention relates to power divider and/or combiner components of the coaxial guide type.

### BACKGROUND OF THE INVENTION

A power divider/combiner component must have a wide operating frequency band, meaning a band over which its characteristics remain substantially constant. Notably, the component has low losses. It has low ripples, meaning low variations in transmission losses.

Traditional solutions, based on transmission lines etched on a conductive layer of a printed circuit board—PCB, induce too significant power losses. Consequently, it is necessary to use alternative solutions, notably spatial dividers/combiners.

A spatial divider/combiner is based on a waveguide (coreless guide) or a coaxial guide (core guide).

To date, spatial dividers/combiners include an effective solution in terms of admissible radiofrequency—RF power and low losses.

However, as presented, e.g., in document U.S. Pat. No. 7,215,220B1, spatial dividers/combiners include multiple subassemblies of complex mechanical parts and RF substrates, making them bulky, heavy, and expensive. Interconnections with active elements are complex to achieve.

Moreover, the whole is poorly suited to automatic manufacturing processes and requires numerous manual operations, poorly adapted to mass production and/or low cost.

Furthermore, when the spatial dividers/combiners are formed by a coaxial guide (cylindrical or rectangular section), same is often oversized and thus likely to present performance degradations, notably transmission variations, depending on symmetry defects whether internal (related to the manufacture thereof) or external (related to elements connected to the path thereof). Impedance transformations, carried out using antipodal lines, have low cutoff frequencies that significantly limit the bandwidth of such power divider/combiner components.

### SUMMARY OF THE INVENTION

The aim of the invention is to address these issues by proposing a new type of power divider/combiner component.

To this end, the invention concerns a power divider/combiner component of the coaxial guide type, characterized in that it is fabricated using “substrate integrated waveguide” technology, in a multilayer integrated circuit board, which includes a stack of a plurality of conductive layers separated from each other by insulating layers.

According to other advantageous aspects of the invention, the component comprises one or a plurality of the following features, taken individually or in any technically possible combination:
the coaxial guide includes an external conductor and an internal conductor, the external conductor being grounded, the internal conductor circulating inside the external conductor and connecting a first port of the component to each second port of a plurality of second ports of the component;
the external conductor includes at least one upper ground plane, defined in an upper conductive layer of the multilayer integrated circuit, a lower ground plane, defined in a lower conductive layer of the multilayer integrated circuit, and a plurality of lateral metallized vias electrically connecting the upper and lower ground planes;
the component includes successively, along a longitudinal axis: an input impedance transformation section, on which the internal conductor includes a common track connected to the first port; an output path separation section, on which the internal conductor includes a plurality of branched tracks; and, an intermediate subdivision section into several routes, on which the internal conductor includes a plurality of intermediate tracks, which are superimposed depending on a thickness of the multilayer integrated circuit and connected to each other by vias, the plurality of intermediate tracks including at least one central intermediate track connected to the common track of the input section, and at least one subdivision intermediate track presenting a plurality of branches, each branch being connected to a branched track of the output section;
the common track has one or a plurality of impedance transformation stages, the width of the common track widening between the two ends of an impedance transformation stage;
the central track has first and second impedance transformation stages arranged successively, a first pair of first ground planes arranged on either side of the central track being associated with the first stage and a second pair of second ground planes arranged on either side of the central track being associated with the second stage, the first ground planes covering the first and second stages, the second ground planes covering the second stages only, the second ground planes being closer to the central layer than the first ground planes;
each branched track includes at least one section widening to adjust an impedance of the waveguide on the output section;
the intermediate section constitutes a spatial divider/combiner;
the intermediate section includes a plurality of first intermediate tracks carried by as many different layers of the multilayer circuit, each first intermediate track including a plurality of branches, each branch of the intermediate section being connected to a corresponding branched track among the branched tracks of the output section;
the intermediate section includes a plurality of second intermediate tracks, each second intermediate track including a plurality of branches, which are not connected, each second intermediate track including at least one subdivision portion disposed directly above at least one subdivision portion of a first intermediate track;
the output section includes an intermediate ground plane between the branched tracks connected to the branches of a first intermediate track and the branched tracks connected to the branches of another first intermediate track; and
the plurality of second ports forms a matrix on a plurality of N levels, each level corresponding to a different layer of the multilayer circuit, each level including M second ports.

### BRIEF DESCRIPTION OF THE DRAWINGS

The invention will become clearer upon reading the following description, given solely by way of non-limiting example, and made with reference to the drawings wherein:

FIG. 1 is a schematic representation of a power amplification device in top view, integrating two components in SIW technology according to the invention, the first operating as a power divider and the second as a power combiner;

FIG. 2 is a schematic top view representation of an embodiment of the power divider component of FIG. 1;

FIG. 3 represents different cross-sections of the component of FIG. 2; and

FIG. 4 is a schematic exploded perspective representation of a subdivision section of the component of FIG. 2.

### DETAILED DESCRIPTION OF THE INVENTION

The power divider/combiner component according to the invention is a power divider/combiner component of the coaxial guide type fabricated using SIW technology.

The “substrate integrated waveguide”—SIW technology allows the component to be fabricated within the thickness of a multilayer printed circuit board.

The SIW technology allows all technical performance and industrial constraints to be met. This solution improves the size, cost, and weight of the component, for RF performances halfway between those obtained for mechanical spatial dividers/combiners and those obtained for traditional dividers/combiners.

In the following, the case of a power divider component will be more particularly presented, i.e., a component used as a power divider, while keeping in mind that it is equally a power combiner component, i.e., the same component but used as a power combiner. This actually depends on how this component is integrated into the electrical assembly made on the board.

The way to fabricate a power divider using SIW technology mainly concerns the way to fabricate the subdivision of paths, while ensuring high performance over a wide bandwidth, these high performances being characterized in particular in terms of RF signal transmission ripple and low insertion losses.

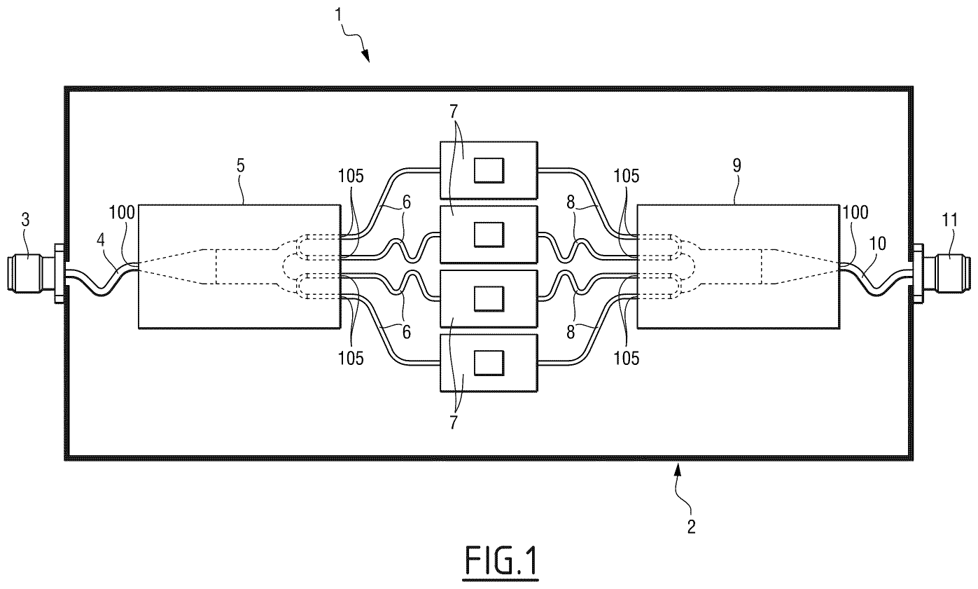

FIG. 1 is a schematic top view representation of a power amplification device.

The amplification device 1 is an electronic circuit fabricated on a printed circuit board—PCB (“Printed circuit board”) multilayer, or PCB board 2.

The PCB board 2 results from the stacking of a plurality of conductive copper layers, two successive layers being separated by an insulating layer, in a dielectric material.

The PCB board 2 includes:
an input connector 3, connected to a signal generation electronics to be amplified (the generation electronics is not shown in the figure);
a bank of N×M power amplifiers, referenced by the number 7 in FIG. 1, where N is an integer strictly greater than one and M is an integer preferably greater than one. In the present embodiment, M is equal to two and N is equal to four. Thus, four amplifiers 7 are mounted on the upper face of the PCB board 2 (and therefore visible in FIG. 1) and four amplifiers are mounted on the lower face of the PCB board 2 (and therefore not shown in FIG. 1); and
an output connector 11, to transmit the amplified signal, e.g., to a radiating element of an antenna.

The PCB board 2 integrates a component according to the invention used as a power divider.

This component 5 includes a first port 100 connected, by a microstrip line 4 etched in the PCB board 2, to the input connector 3.

The component 5 includes a plurality of second ports 105, each second port being connected, by a microstrip line 6 etched in the PCB board 2, to a particular amplifier 7 of the amplifier bank.

The PCB board 2 integrates a component according to the invention used as a power combiner.

This component 9 includes a plurality of second ports 105, each port 105 being connected, by a microstrip line 8 etched in the PCB board 2, to a particular amplifier 7 of the amplifier bank.

The component 9 includes a first port 100 connected, by a microstrip line 10 etched in the PCB board 2, to the output connector 11.

The power divider component 5 and the power combiner component 9 are identical. They are mounted head-to-tail in the circuit of device 1.

In the following, the component 5 will be more particularly described, but a similar description could be made for the component 9.

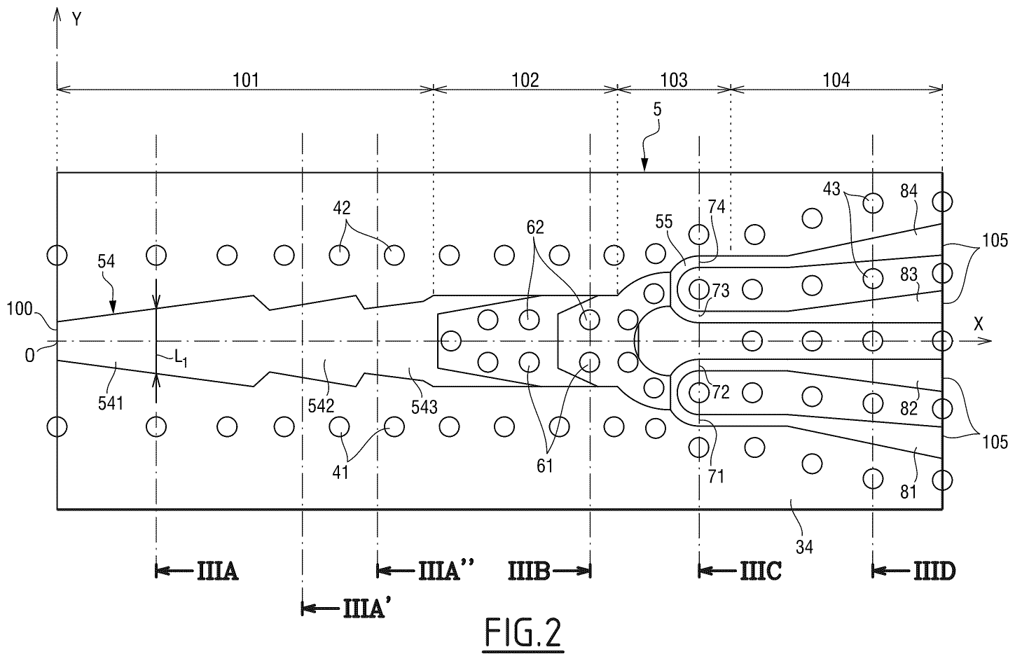

A preferred embodiment of a power divider component using SIW technology will now be presented with reference to FIGS. 2-4.

FIG. 2 is a schematic top view representation of the power divider component 5, the ground planes of the different layers being omitted for readability. FIG. 2 thus represents the tracks of the internal conductive layers constituting the core of the coaxial guide of component 5.

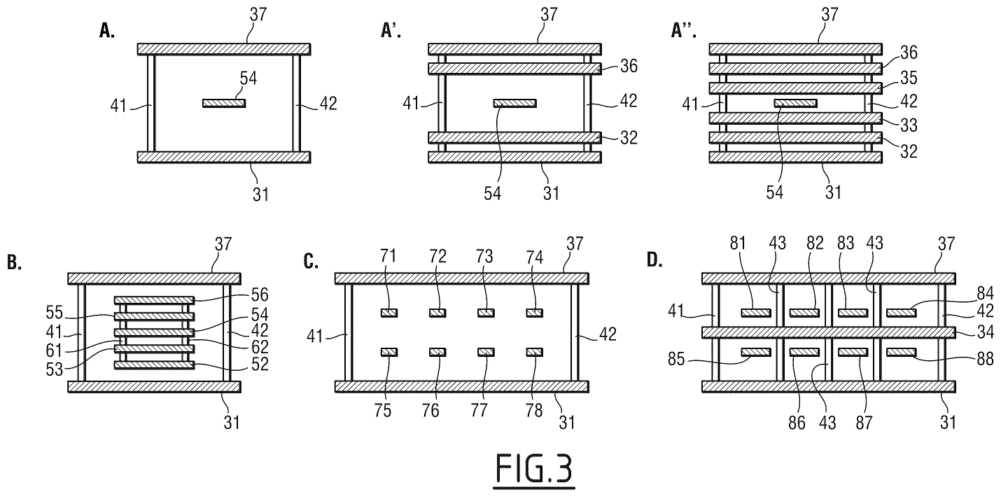

Different cross-sections of component 5 through transverse planes are shown in FIG. 3.

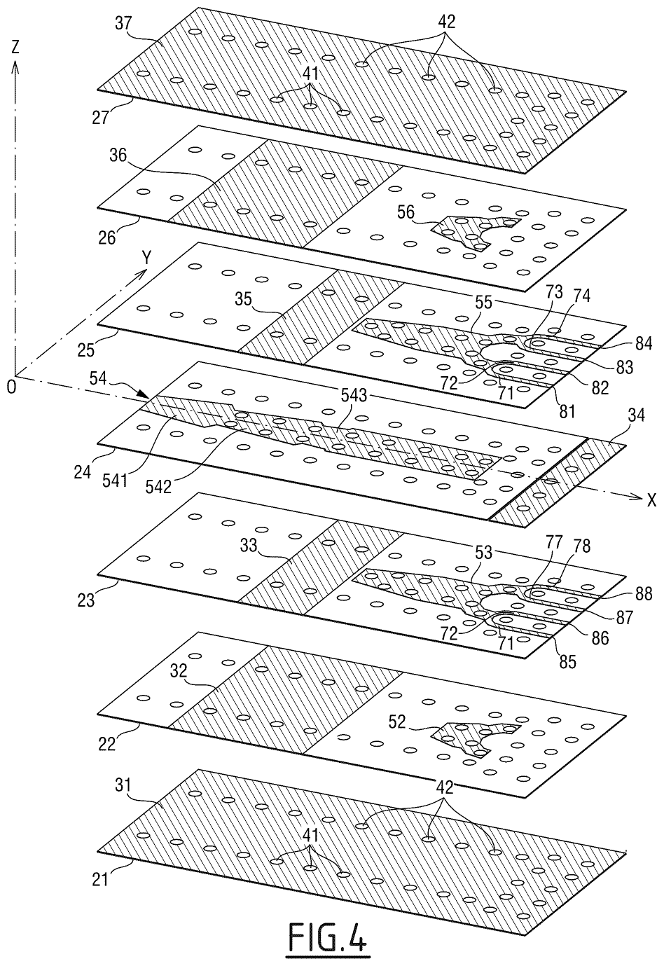

Finally, FIG. 4 is a perspective representation of component 5.

Component 5 is a spatial divider, more specifically a spatial divider of the coaxial guide type.

Component 5 is fabricated within the thickness of PCB board 2.

In the present embodiment, PCB board 2 results from the stacking, along a Z-axis, of seven conductive layers 21 to 27, each conductive layer being isolated from the previous one by an insulating layer. More specifically, as illustrated in FIG. 4, PCB board 2 includes:
a lower external layer 21;
an upper external layer 27;
a central internal layer 24;
between the lower external layer 21 and the central internal layer 24, a second lower intermediate internal layer 22 and a first lower intermediate internal layer 23; and
symmetrically, between the central internal layer 24 and the upper external layer 27, a first upper intermediate internal layer 25 and a second upper intermediate internal layer 26.

A conductive layer is etched to define tracks (which may be planes, notably ground planes).

The tracks of two (or more) conductive layers of PCB board 2 may be electrically connected by one or a plurality of metallized vias circulating through the thickness of PCB 2.

An orthonormal XYZ reference is attached to an origin point O, which is located on the intermediate layer 24, at the level of the first port 100, constituting the input port of the component operating as a power divider.

The Z-axis is the stacking axis of the layers of PCB board 2.

The X-axis constitutes the longitudinal axis of component 5 from port 100 to the second ports 105, constituting the output ports of the component operating as a power divider.

The Y-axis is the transverse axis.

Thus, the plane of the central internal layer 24 lies in the XY plane.

In the present embodiment, component 5 is symmetrical with respect to the XZ plane and the XY plane.

As illustrated in FIG. 2, component 5 may be subdivided along the X-axis into successive sections.

The first section 101 has an SIW structure similar to that of a classic stripline transmission line.

More precisely, as illustrated in cross-section A of FIG. 3, component 5 has a track forming an upper ground plane 37, defined in the upper external conductive layer 27, and a track forming a lower ground plane 31, defined in the lower external layer 21.

The upper and lower ground planes 37 and 31 are connected by rows of lateral vias 41 and 42.

The assembly formed by the two ground planes 37 and 31 and the lateral vias 41 and 42 constitutes the external conductor, or shielding, of the stripline.

The internal conductor, or core, of the stripline is a so-called “common” line.

The common line is, in the present embodiment, made of a central track 54, defined in the central internal layer 24.

The central internal layer 24 is electrically connected to the input port 100 of component 5, and therefore to the input connector 3 to receive the signal to be amplified.

The central track 54 has a width L1 and a thickness E1.

The central track has a low thickness and, as such, the first section 101 corresponds to a stripline rather than a coaxial guide.

The central track 54 is shaped to perform an impedance transformation function.

The width of the central track 54 gradually widens as one moves along the X-axis.

Knowing that at a point along the X-axis, the value of the width of a track defines the impedance of this track at this point, the widening of the central track 54 allows for a decrease in impedance.

The impedance of the central track 54 at its proximal end, i.e., the input of the first section 101, is chosen by configuring component 5 equal, e.g., to a usual or standard nominal impedance of 50 ohms.

The impedance of the central track 54 at its distal end, i.e., the output of the first section 101, is chosen by configuring component 5 equal, e.g., to 30 Ohms.

Advantageously, to achieve a large decrease in impedance between the ends of track 54 without leading to a track with too large a width, the central track 54 is shaped in a sawtooth manner to present three successive impedance transformation stages. The transition between two successive stages is associated with the introduction of a pair of ground planes.

Thus, the first stage 541 is located between the ground planes 31 and 37 of layers 21 and 37 (as illustrated in cross-section A of FIG. 3), moreover the second stage 542 is located between the ground planes 32 and 36 reserved in layers 22 and 26 (as illustrated in cross-section A′ of FIG. 3), and moreover the third stage 543 is located between the ground planes 33 and 35, reserved in layers 23 and 25 (as illustrated in cross-section “A” of FIG. 3).

The waveguide has only one central track, which forms the core at the center of the structure and ground planes, which form the shielding and gradually approach the central track.

The advantage of this stepped structure is to transform a standard impedance, typically 50 Ohms, into a low impedance, typically less than 10 ohms, over a wide frequency band and with minimal RF losses and, correspondingly maximum power handling.

The median section of component 5, called the path subdivision section, includes a second section 102 and a third section 103.

The ground planes of the intermediate layers that had gradually approached the core in section 101 disappear at the transition with section 102.

The second section 102 has an SIW structure similar to that of a rectangular section low impedance coaxial guide. The core thickens in the Z direction progressively in section 102.

More precisely, the external conductor constituted by the upper and lower ground planes, 31 and 37, and the lateral vias 41 and 42 electrically connecting these ground planes is illustrated in cross-section B of FIG. 3.

The internal conductor is now constituted by a so-called “subdivision” line. This is constituted by a plurality of internal tracks 52 to 56 superimposed on each other, respectively etched into the internal conductive layers 22 to 26.

The internal tracks are electrically connected to each other by central vias, e.g., distributed in two rows, 61 and 62.

The internal conductor now having a high thickness, one may speak of a waveguide for the second section 102.

The central track 54 of the second section 102 constitutes the continuity of the central track 54 of the first section 101.

The tracks 52, 53, 55, and 56 are therefore brought to the potential of the central track 54 by vias 61 and 62.

Advantageously, the internal tracks may have a width that evolves along the X-axis to provide the second section 102 with an impedance transformation function, in this case, impedance reduction, to present, at the output end of the second section, a very low impedance, e.g., 10 Ohms.

The third section 103 has an SIW structure of path separation per se. Same has N×M outputs.

More precisely, the external conductor of the coaxial guide constituted by the upper ground plane 37 and lower ground plane 31 and the lateral vias 41 and 42 is illustrated in section C of FIG. 3.

The internal conductor of the coaxial guide includes tracks called first lower and upper internal tracks, 53 and 55, respectively carried by the first lower and upper internal conductive layers, 23 and 25.

For example, the first upper internal track 55 subdivides, in a subdivision zone, into a plurality of four branches, 71 to 74 respectively, and the first lower internal track 53 subdivides into a plurality of four branches, 75 to 78 respectively.

The distal end of each of these branches constitutes the output of the path subdivision section.

Preferably, the internal conductor of the coaxial guide also includes tracks called second upper and lower internal tracks, 52 and 56, respectively carried by the second lower and upper internal conductive layers, 22 and 26.

The second internal tracks 52 and 56 interrupt substantially above the subdivision zones of the first internal tracks 53 and 55. They have a capacitive role to improve power transfer.

The principle of the path separation section is thus that of spatial dividers/combiners, i.e., the fields of the mode propagated by the internal conductor of the coaxial guide, are subdivided in space into N×M approaching modes (to ensure the smoothest possible transition). Here M represents the number of levels, i.e., of first internal tracks, and N represents the number of branches of each first internal track.

The path subdivision section is designed to ensure optimal distribution (typically equal distribution of powers and impedances) towards the high impedance branched lines constituting the fourth section 104 of component 5.

The internal conductor presents, upstream of the subdivision, a sufficient cross-section to allow an efficient transition to the M×N high impedance branched lines.

Conversely, the cross-section of each branch of the subdivision is sufficiently reduced to minimize the influence of parasitic propagation modes.

The location of the ground vias in the transition zone is sensitive and must be adjusted.

The fourth section 104 has an SIW structure similar to that of a plurality of parallel stripline transmission lines.

It performs a distance function for each of the branched lines located in the extension of each of the branches of the third section 103.

Advantageously it also performs an impedance transformation function.

More precisely, as illustrated in section D of FIG. 3, in addition to the upper and lower ground planes, a half intermediate ground plane 34 is defined in the central conductive layer 24. These three ground planes are connected by rows of vias, not only rows of lateral vias 41 and 42 but also rows of intermediate vias 43.

The tracks defined in the first upper and lower internal layers, which constitute as many high impedance branched lines, are now isolated from each other.

Thus, a matrix of N×M striplines (or coaxial guides by extension) is formed. In the present embodiment, there are four striplines per level and two levels in the thickness of PCB board 2.

The widening of the width of a branched line forming the core of a stripline between the input and output of the fourth section 104 allows the impedance to be reduced.

The impedance is, e.g., lowered from 80 Ohms at the input to 50 Ohms at the output.

The distance between the lateral vias is increased to allow for the spatial separation of the different paths.

FIG. 4 is an exploded perspective representation of component 5.

Only the conductive layers are represented in this figure, and the tracks or ground planes defined in these layers after etching are represented with hatching.

The upper and lower ground planes 31 and 37 connected by lateral vias, 41 and 42, are shown. It should be noted that in FIG. 4, only the intersection of a via with a conductive layer is represented.

In the central layer 24, the central track 54 extends to a substantially rectangular distal end.

The ground planes 32 and 36 begin at the transition between the first and second stages, 541 and 542 of the central track 54.

The ground planes 33 and 35 begin at the transition between the second and third stages, 542 and 543 of the central track 54.

The ground planes 32, 33, 35, and 36 interrupt at the end of the third stage 543, i.e., between the first and second sections 101 and 102 of component 5.

The first upper intermediate internal track 55 (lower 53 respectively), electrically connected to the central track 54 by central vias, 61, 62, has a trapezoidal proximal end.

Same runs rectilinearly along the longitudinal X-axis.

At the level of the third section 103, same first subdivides into two branches, then each branch subdivides in turn into two new branches. The four branches 71 to 74 (75 to 78 respectively) are connected to the four branched lines 81 to 84 (85 to 88 respectively).

The geometry of each subdivision is optimized to transmit power to the branched lines as gradually as possible.

At the output of the third section 103, an intermediate ground plane 34, reserved in the central layer 24, allows the branched lines of the two different levels to be isolated.

Vias 43 between the ground planes allow the branched lines of the same level to be isolated.

The second upper internal track 56 (lower 52 respectively), electrically connected to the central track 54 and to the first internal tracks 53 and 55 by central vias, 61, 62, extends between a trapezoidal proximal end and a pair of substantially rectangular distal ends, resulting from a subdivision into two extensions of the body of the second internal track.

The subdivision portion of a second internal track is essentially located directly above the first subdivision portion of the first upper and lower internal tracks and the distal end of the central track 54.

The extensions thereof are connected by vias to the first upper and lower internal tracks.

These extensions constitute adjustable capacitive reinforcements.

The shape of the subdivision portion of internal tracks 52 and 56 (width and length of branches/branchings) is adjusted to optimize the adaptation of impedances present on either side of the interface between the third and fourth sections 103 and 104 of component 5.

The component according to the invention may be fabricated in different ways.

In general, the component has N×M paths, distributed over M levels or layers of the PCB and, on each level, in N branched lines.

The subdivision section may be fabricated according to different geometries to create fewer or more paths: e.g., to generate only four paths, it is possible not to produce the second subdivision; e.g., again, to create sixteen paths, it is possible to produce a third order of subdivision; in yet another example, to create another number of paths per level, it is possible to create subdivisions by three branches rather than by two branches.

This structure, adapted to function primarily as a divider, may also function, in reverse, as a power combiner on similar signals (in spectrum, phase, and amplitude). The recombination of waves carried by the N×M branched lines towards the common line is also optimal.

Advantageously, other ground planes may be provided to reinforce the isolation of the central core of the coaxial guide. In particular, the central conductive layer 24 includes, on either side of the central track 54, and at a distance from its edges, two lateral half-ground planes. Same are connected to the upper and lower ground planes by the lateral vias.

The solution presented above allows for controlling ripples over a wide bandwidth, phase, power, and impedance adaptation disparities, in particular minimizing the presence and excitation of parasitic modes.

Advantageously, the shape of the subdivision zone results from three-dimensional electromagnetic simulations to ensure the best compromise between power handling, low losses, and wide bandwidth.

Regarding the insulating layers of the PCB, substrates of various permittivities and/or thicknesses may be used simultaneously. Preferably, substrates of higher permittivity are located near the ground planes.

Instead of a mechanical assembly, the component according to the invention is fabricated using SIW technology, being more economical, lighter, and with reduced size.

Being compact, the component according to the invention reduces the risk of carrying multiple transmission modes, which are sources of performance degradation, notably at high frequency.

Instead of a structure that separates paths with slot-type interfaces, then transitions to microstrip lines, called antipodal lines, the component according to the invention uses subdivisions of tracks (or ribbon lines) of suitable impedances, combined with impedance transformers. The component according to the invention has a particularly low cutoff frequency, as the component is not constrained by the short-circuit imposed by the implementation of antipodal lines.

Thus, the component according to the invention is characterized by a wide bandwidth.

The component according to the invention finds multiple applications in power amplification, as a path formation element on wideband electronically scanned active antennas, particularly for embedded antennas.

1. A power divider/combiner component comprising:
a multilayer integrated circuit board, comprising a stack of a plurality of conductive layers separated from each other by insulating layers;
a coaxial guide fabricated using a substrate integrated waveguide technology, comprising:
an external conductor that is grounded, comprising:
at least one upper ground plane, defined in an upper conductive layer of said multilayer integrated circuit;
a lower ground plane, defined in a lower conductive layer of said multilayer integrated circuit; and
a plurality of lateral metallized vias, the lateral metallized vias being electrically connecting said upper and lower ground planes; and
an internal conductor running inside said external conductor and connecting a first port of the component to each second port of a plurality of second ports of the component; and
successively, along a longitudinal axis:
an input impedance transformation section, on which said internal conductor comprises a common track connected to the first port;
an output path separation section, on which said internal conductor comprises a plurality of branched tracks; and
an intermediate subdivision section into several paths, wherein, on the intermediate section, said internal conductor comprises a plurality of intermediate tracks, which are superimposed according to a thickness of said multilayer integrated circuit and connected to each other by vias, the plurality of intermediate tracks comprising at least one central intermediate track connected to the common track of said input section, and at least one subdivision intermediate track presenting a plurality of branches, each branch being connected to a branched track of said output section, the intermediate section constituting a spatial divider/combiner.

2. The component according to claim 1, wherein the common track comprises one or more impedance transformation stages, the width of the common track widening between the two ends of an impedance transformation stage.

3. The component according to claim 2, wherein the central track comprises first and second impedance transformation stages arranged successively, a first pair of first ground planes arranged on either side of the central track being associated with the first stage and a second pair of second ground planes arranged on either side of the central track being associated with the second stage, the first ground planes covering the first and second stages, the second ground planes covering the second stages only, the second ground planes being closer to the central layer than the first ground planes.

4. The component according to claim 1, wherein each branched track includes at least one section widening to adjust an impedance of the waveguide on said output section.

5. The component according to claim 1, wherein said intermediate section comprises a plurality of first intermediate tracks carried by as many different layers of said multilayer circuit, each first intermediate track comprising a plurality of branches, each branch of said intermediate section being connected to a corresponding branched track among the branched tracks of said output section.

6. The component according to claim 5, wherein said intermediate section comprises a plurality of second intermediate tracks, each second intermediate track including a plurality of branches, which are not connected, each second intermediate track including at least one subdivision portion disposed directly above at least one subdivision portion of a first intermediate track.

7. The component according to claim 5, wherein said output section comprises an intermediate ground plane between the branched tracks connected to the branches of a first intermediate track and the branched tracks connected to the branches of another first intermediate track.

8. The component according to claim 1, wherein the plurality of second ports forms a matrix on a plurality of N levels, each level corresponding to a different layer of said multilayer circuit, each level including M second ports.
